(19) United States
(12) Patent Application Publication
(10) Pub. No.: US 2003/0154039 A1
(43) Pub. Date: Aug. 14, 2003

(54) Program, method and apparatus associated with controlling/monitoring panels, involving parameters and display additions

(76) Inventor: Vlad Moldovan, Brookfield, WI (US)

Correspondence Address: WOOD, HERRON & EVANS, LLP, 2700 CAREW TOWER, 441 VINE STREET, CINCINNATI, OH, 45202, US

(21) Appl. No.: 10/071,023

(22) Filed: Feb. 8, 2002

(51) Int. Cl. G06F 19/00; G01R 21/00; G01R 21/06

(52) U.S. Cl. 702/61

(57) ABSTRACT

In the method and apparatus of the present invention, electrical usage is displayed and calculated by multiplying the percentage ofmaximum power already displayed by the operating hours. The result, the kWh, is multiplied by the average unit price for the electricity to determine the cost of electrical energy used by the specific equipment in the particular application in U.S. dollars, or such other unit of monetary measure. This cost shall be displayed together with the savings in kWh and U.S. dollars.

### FIELD OF THE INVENTION

This invention relates to electrical controls/monitoring panels for equipment using variable frequency drives. More particularly, it relates to control/monitoring panels used with motor drives for displaying and calculating operating data such as kilowatt-hour (kWh) usage, kWh savings and money savings due to the use of the variable frequency drives relative to the operation of an electrical motor in any number of variable frequency drive applications such as fans, pumps, compressors, or the like.

### BACKGROUND OF THE INVENTION

The use of motor controls, motor control equipment and electronic controls for motors is well known in the electrical arts. It is old art that a local motor control/monitoring panel is provided that has a display, keys for changing programming parameters and keys for controlling drive operation. The local control/monitoring panel may utilize a multiple line, alpha numeric, liquid crystal display (LCD), although other display formats may be utilized. The display can show operating data values and operating condition values.

It is also old art that such control/monitoring panels display data items such as average phase current of the motor (in amperes or “A”), output frequency of the drive (in hertz or “Hz”), hours run by the motor, actual power delivered to the motor (in kilowatts or “kW”; in horsepower or “HP”) and so on. Presently, however, control/monitoring panels do not show the electrical usage in kilowatt-hours (or “kWh”), the money spent for electricity used by a specific motor or piece of equipment run by the motor, and the savings due to the variable frequency drive that is used to run the motor or equipment.

Accordingly, it is an object of the method and apparatus of the present invention to add at least one additional parameter to the display panel to show the money spent for electricity used by a specific motor or piece of equipment run by the motor, and the savings due to the variable frequency drive that is used to run the motor or equipment. It is another object of the method and apparatus of the present invention to add the parameter that is the average cost of electricity used in the application, which cost shall be determined by the end user. These and other objects will become apparent from the detailed description that follows.

### SUMMARY OF THE INVENTION

As mentioned previously, a typical motor control display panel will show the kW as a percentage of maximum motor power. It will also typically show the operating hours for the particular motor application. It should also be noted here that other units of measure could be displayed for measuring electrical power (e.g., HP or megawatts) and for measuring time.

In the method and apparatus of the present invention, electrical usage is displayed and calculated by multiplying the percentage of maximum power already displayed by the operating hours. The result, the kWh, is multiplied by the average unit price for the electricity to determine the cost of electrical energy used by the specific equipment in the particular application in U.S. dollars, or such other unit of monetary measure. This cost shall be displayed together with the savings in kWh and U.S. dollars. The foregoing and other features of the method and apparatus of the present invention will be apparent from the detailed description that follows.

### BRIEF DESCRIPTION OF THE DRAWINGS

FIG. 1 is a schematic diagram illustrating kWh usage and the cost of electrical energy used by equipment in accordance with the method of the present invention.

FIGS. 2A and 2B are schematic diagrams expanding on the diagram shown in FIG. 1 and illustrating kWh and monetary savings by equipment in accordance with alternative methods of the present invention.

FIG. 3 illustrates a parameter display on a control/monitoring panel showing kWh and money savings.

FIG. 4 illustrates a parameter display showing money spent for equipment electrical usage and kWh.

FIG. 5 illustrates a comparative parameter display where the control/monitoring panel is used in a fan application.

FIG. 6 illustrates a comparative parameter display where the control/monitoring panel is used in a pump application.

### DETAILED DESCRIPTION

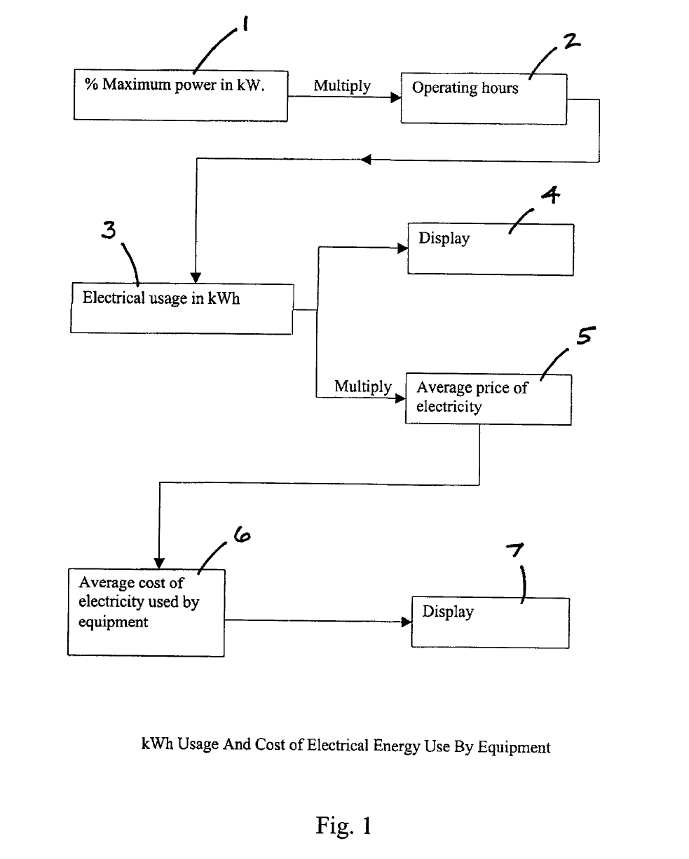

Referring now to the drawings in detail, wherein like numbered elements represent like elements throughout, FIG. 1 schematically represents kWh usage and the cost of electricity used by equipment in a typical application. It is to be understood throughout this detailed description that the measuring means and the programming means for effecting motor control is provided by hardware and programmable software that is integral to the motor control panel. The programming means includes a programmable logic controller that functions according to a preprogrammed scheme as contemplated by this disclosure. The precise program could assume many different configurations and utilize different algorithms. The important function is that the control/monitoring panel, and the programming means and all related equipment be capable of making, controlling, monitoring and recording each of the measurements and displays as disclosed herein.

As shown in FIG. 1, the percentage of maximum power 1 is measured as are the counted hours 2 of operation of the motor in the particular application. The maximum power 1 is multiplied by the operating hours 2 to realize electrical usage 3 shown in kWh. This is displayed 4 on the panel. The electrical usage 3 in kWh is then multiplied by the average price of electricity 5 to arrive at the cost of the electricity used 6 by the equipment. This is also displayed 7 on the panel.

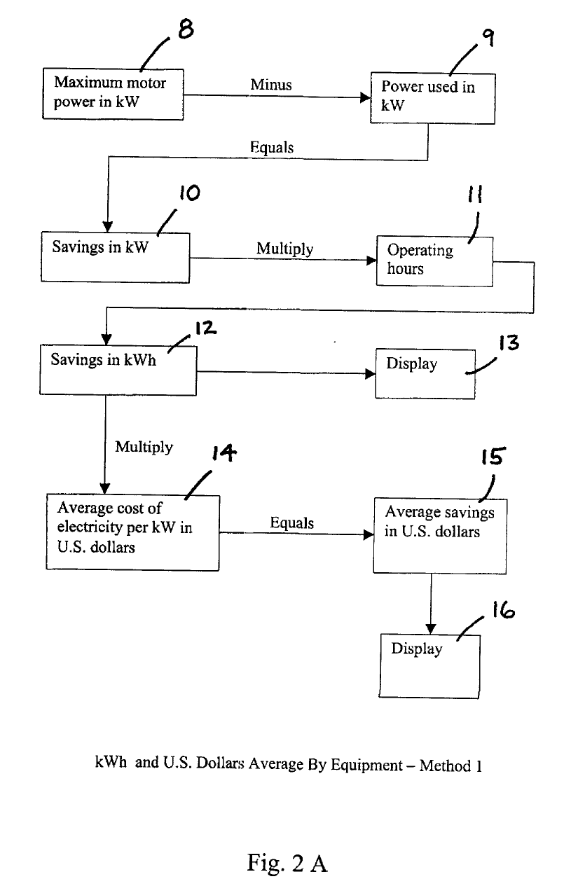

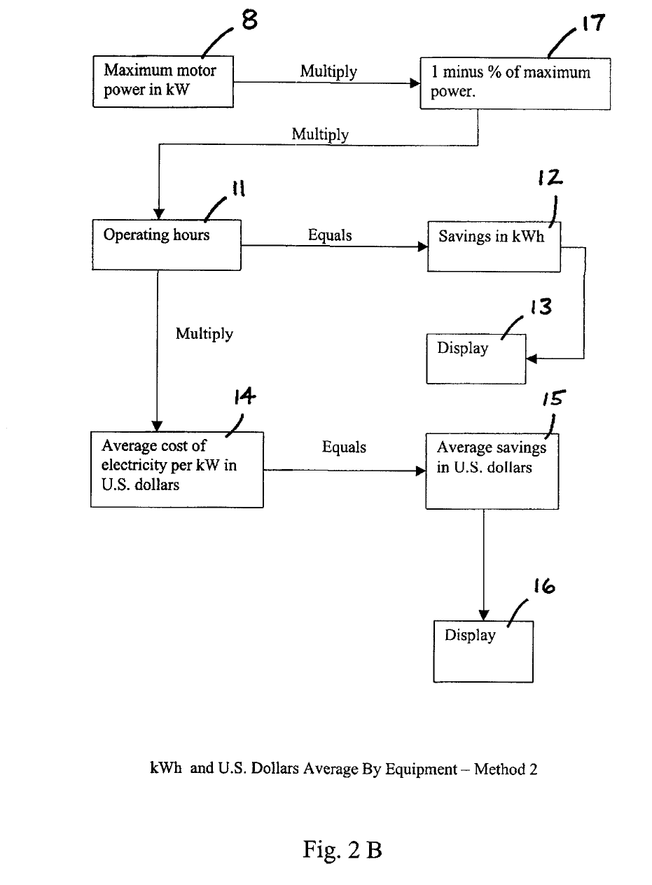

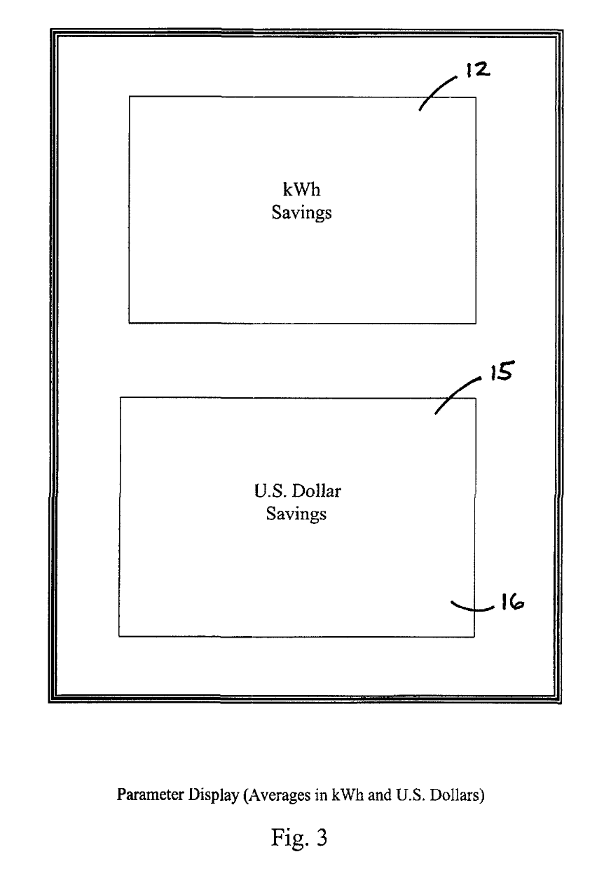

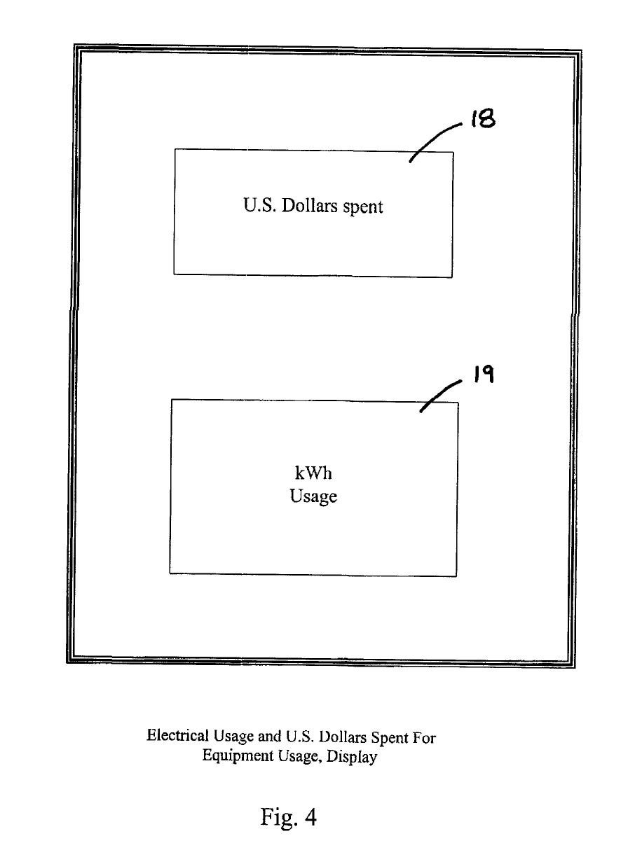

Referring now to FIGS. 2A and 2B, the savings in kWh and U.S. dollars shall also be determined and displayed and this is part of the method and apparatus of the present invention. The savings can be calculated by one of two methods. Referring first specifically to FIG. 2A, the power used 9, in kW, is subtracted from the maximum motor power 8, also in kW. This equals the savings 10 in kW. Multiplying the savings 10 by the operating hours 11 represents the savings 12 in kWh. This savings 12 is displayed 13 on the control panel. The savings 12 in kWh, in turn, is multiplied by the average cost of electricity 14 to arrive at the energy savings 15 in U.S. dollars. This parameter of energy savings 15 in U.S. dollars is similarly displayed 16 on the panel. In the alternative, and referring specifically to FIG. 2B, a number of one (1) less the percentage of maximum power 17 is multiplied by the maximum motor power 8, in kW. This product, in turn, is multiplied by the number of operating hours 11 to arrive at the savings 12 expressed in kWh. As before, the savings 12 in kWh is multiplied by the average cost of electricity 14 to arrive at the energy savings 15 in U.S. dollars. This parameter of energy savings 15 is similarly displayed 16 on the control panel. See also FIG. 3 which illustrates the display of energy savings expressed in kWh 12 and in U.S. dollars 15, 16 and FIG. 4 which illustrates the display of money spent 18 for electrical usage and kWh usage 19 in a given unspecified application where variable frequency drives are used.

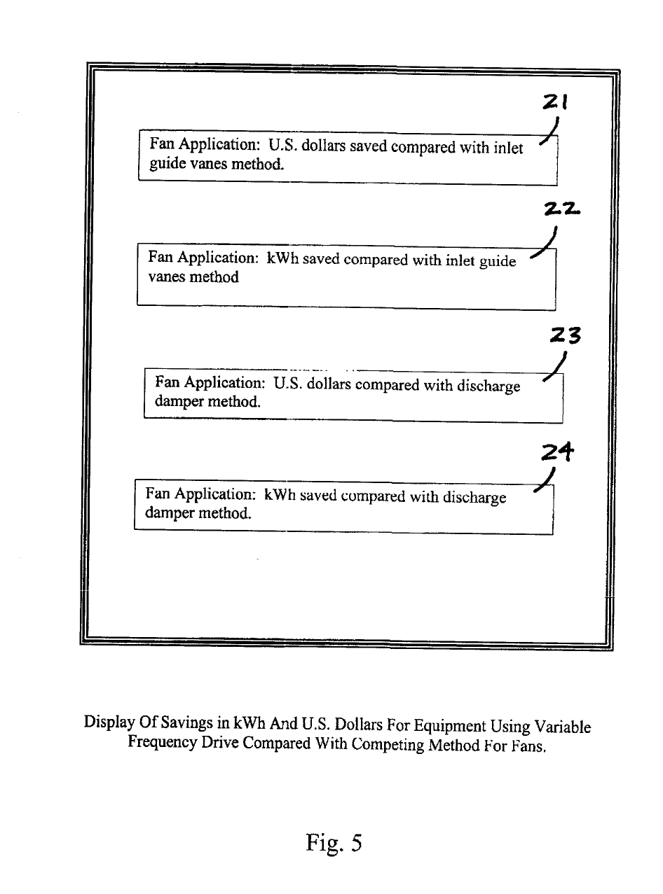

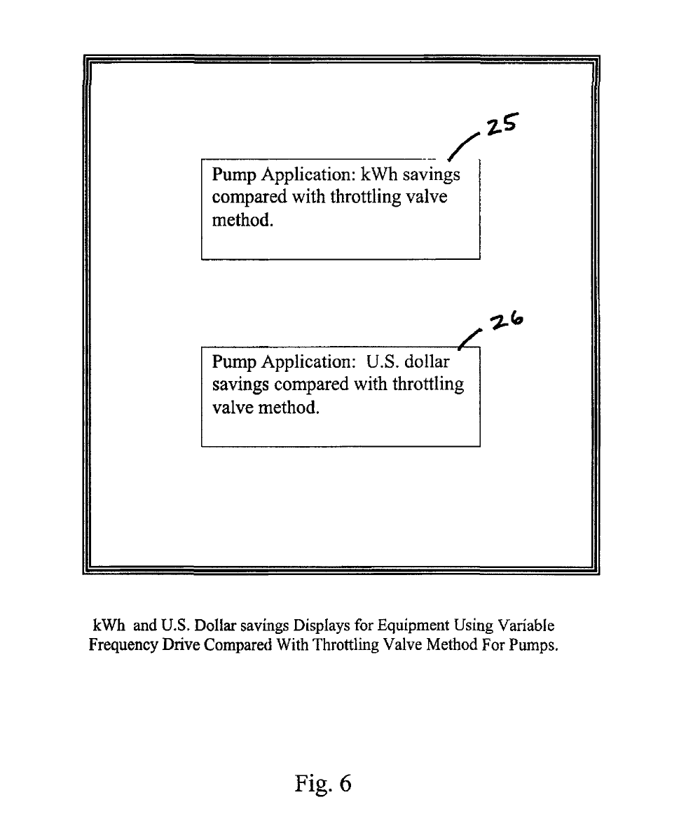

FIG. 5 illustrates a display in a variable frequency fan application wherein the money saved 21 and the kWh saved 22 is compared, for example, with a fan application where inlet guide vanes are utilized. It also illustrates a comparative display in a fan application wherein money saved 23 and kWh 24 saved is compared with an application where a discharge damper is used. FIG. 6 similarly illustrates a display in a variable frequency pump application wherein kWh saved 25 and the money saved 26 is compared, for example, with a pump application where a throttling valve is used. It is to be understood that the comparative display contemplated by the method and apparatus of the present invention could be utilized in almost any application where motors with variable frequency drives are used, aside from the fans and pumps discussed herein.

Based upon the foregoing, it will be apparent that there has been provided a new and useful method and apparatus that adds at least one additional parameter and a new display panel to show the money spent for electricity used by a specific piece of equipment run by the motor, and the savings due to the variable frequency drive that is used to run the motor. The parameter added is the average cost of electricity used in the application, as determined by the end user.

The principles of this invention having been fully explained in connection with the foregoing, I hereby claim as my invention:

1. A method for controlling/monitoring a motor control panel used with electrical equipment, said panel being functionally adapted to visually display a percentage of maximum power, to multiply the percentage ofmaximum power by the number of operating hours to determine electrical usage, and to visually display electrical usage, comprising the steps of
inputting the average price of electricity,
multiplying electrical usage by the average price of electricity to determine the cost of electrical energy used, and
visually displaying the cost of electrical energy used.

2. The method of claim 1 wherein the cost of electrical energy used is displayed in U.S. dollars.

3. The method of claim 1 including the step of providing multiple visual displays for comparing savings due to variable frequency drives with competing methods, including inlet guide vanes, discharge damper and throttling valves.

4. A method for controlling/monitoring a motor control panel used with electrical equipment, said panel being functionally adapted to visually display a percentage of maximum power, to multiply the percentage of maximum power by the number of operating hours to determine electrical usage, and to visually display electrical usage, comprising the steps of
inputting the average price of electricity,
multiplying electrical usage by the average price of electricity to determine the cost of electrical energy used,
visually displaying the cost of electrical energy used,
calculating the energy savings, and
visually displaying the energy savings.

5. The method of claim 4 wherein the energy savings is displayed in kilowatt hours.

6. The method of claim 4 wherein the energy savings is displayed in U.S. dollars.

7. The method of claim 4 including the step of providing multiple visual displays for comparing savings due to variable frequency drives with competing methods, including inlet guide vanes, discharge damper and throttling valves.

8. The method of claim 4 wherein maximum motor power is determined and said energy savings calculation step includes the additional steps of
subtracting power used from maximum motor power to determine the savings, and
multiplying the savings by the average cost of the electricity.

9. The method of claim 4 wherein maximum motor power is determined and said energy savings calculation step includes the additional steps of
multiplying maximum motor power by operating hours and by the difference between one and the percentage of maximum motor power to determine the savings, and
multiplying the savings by the average cost of the electricity.

10. A panel for controlling/monitoring a motor used with electrical equipment, said motor control panel including monitoring and programming means, means for multiplying the percentage of maximum power by the number of operating hours to determine electrical usage, and means for visually displaying electrical usage, which comprises
means for inputting the average price of electricity,
means for multiplying electrical usage by the average price of electricity to determine the cost of electrical energy used, and
means for visually displaying the cost of electrical energy used.

11. The panel of claim 10 wherein the cost of electrical energy used is displayed in U.S. dollars.

12. The panel of claim 10 wherein the visual display means includes multiple visual displays for comparing savings due to variable frequency drives with competing methods, including inlet guide vanes, discharge damper and throttling valves.

13. A panel used with electrical equipment for controlling/monitoring one or more motors, said panel including a programmable logic control and being functionally adapted to visually display a percentage of maximum power, means for multiplying the percentage of maximum power by the number of operating hours to determine electrical usage, and means for visually displaying electrical usage, which comprises
means for inputting the average price of electricity,
means for multiplying electrical usage by the average price of electricity to determine the cost of electrical energy used,
means for visually displaying the cost of electrical energy used,
means for calculating the energy savings, and
means for visually displaying the energy savings.

14. The panel of claim 13 wherein the energy savings is displayed in kilowatt hours.

15. The panel of claim 13 wherein the energy savings is displayed in U.S. dollars.

16. The panel of claim 13 wherein the visual display means includes multiple visual displays for comparing savings due to variable frequency drives with competing methods, including inlet guide vanes, discharge damper and throttling valves.
